(19) United States
(12) Patent Application Publication
(10) Pub. No.: US 2006/0128130 A1
(43) Pub. Date: Jun. 15, 2006

(54) Method for fabricating recessed gate structure

(75) Inventors: Se-Aug Jang, Ichon-shi (KR); Heung-Jae Cho, Ichon-shi (KR); Woo-Jin Kim, Ichon-shi (KR); Hyung-Soon Park, Ichon-shi (KR); Seo-Min Kim, Ichon-shi (KR); Tae-Woo Jung, Ichon-shi (KR)

Correspondence Address: TOWNSEND AND TOWNSEND AND CREW, LLP, TWO EMBARCADERO CENTER, EIGHTH FLOOR, SAN FRANCISCO, CA, 94111-3834, US

(73) Assignee: Hynix Semiconductor Inc.

(21) Appl. No.: 11/003,755

(22) Filed: Dec. 2, 2004

(30) Foreign Application Priority Data
Dec. 15, 2003 (KR) 10-2003-91113

(51) Int. Cl. H01L 21/4763

(52) U.S. Cl. 438/589; 438/592

(57) ABSTRACT

The present invention relates to a method for fabricating a recessed gate structure. The method includes the steps of: selectively etching a substrate to form a plurality of openings; forming a gate oxide layer on the openings and the substrate; forming a first conductive silicon layer on the gate oxide layer to form a plurality of valleys at a height equal to or greater than a thickness remaining after an intended pattern is formed; planarizing the first conductive silicon layer until the thickness remaining after the intended pattern formation is obtained, so that the valleys are removed; forming a second conductive layer on a planarized first conductive silicon layer; and selectively etching the second conductive layer, the first conductive silicon layer and the gate oxide layer to form a plurality of the recessed gate structures.

### FIELD OF THE INVENTION

The present invention relates to a method for fabricating a transistor of a semiconductor device; and more particularly, to a method for fabricating a recessed gate structure.

### DESCRIPTION OF RELATED ARTS

As a scale of integration of a semiconductor device has increased, a channel length of a transistor has been conversely shortened. Accordingly, in a general structure of the transistor, there is a problem that a short channel effect that a threshold voltage of the transistor abruptly decreased is apparently pronounced. To solve this problem of an increase in the short channel effect, the transistor provided with a recessed gate structure is proposed. The recessed gate structure, prepared by forming a cavity in a silicon substrate, is one attempt to form a long channel length.

Furthermore, as the scale of integration has increased, a junction leakage also increases in a semiconductor device, e.g., a dynamic random access memory, due to an increased electric field caused by an excessive ion implantation and, becomes a factor for reducing a data retention time. As one of methods to solve this critical problem, the substrate is recessed with a predetermined depth and then, a cell transistor is formed. As a result, the junction leakage is reduced, thereby increasing the data retention time.

Meanwhile, as a semiconductor device is highly integrated, it is required to use a material having a very low resistance as a gate electrode. Exemplary materials of a low resistance electrode are tungsten silicide (WSiₓ), tungsten nitride (WN), titanium nitride (TiN) and tungsten (W), and these materials are typically deposited on polysilicon, thereby lowering a whole resistance of the gate structure.

FIGS. 1A to 1D are cross-sectional views illustrating a conventional process for forming a recessed gate structure.

Referring to FIG. 1A, a region where a transistor will be formed in a substrate 100 provided with various device elements for forming a semiconductor device such as a field oxide layer is selectively etched. That is, the substrate 100 is recessed, thereby forming an opening 101. Afterwards, a gate oxide layer 102 is formed along a profile where the opening 101 is formed.

Subsequently, referring to FIG. 1B, a polysilicon layer 103 is formed on the gate oxide layer 102.

A low pressure chemical vapor deposition (LPCVD) method having an excellent step coverage property is used for forming the polysilicon layer 103. At this time, a valley 104 is formed on an upper portion of the polysilicon layer 103 which corresponds to a middle part of the opening 101 due to a specific deposition property obtained because of the opening 101 formed in the substrate 100.

Next, referring to FIG. 1C, a conductive layer 105 with a low resistance is deposited on the polysilicon layer 103. The conductive layer 105 is formed by using one of W, WSix, WN and TiN.

Meanwhile, since having a bad step coverage property, the conductive layer 105 cannot completely fill the valley 104, thereby forming a void or a seam 106.

Next, referring to FIG. 1D, the conductive layer 105 and the polysilicon layer 103 layer are selectively etched by using a mask pattern, thereby forming a recessed gate structure. Herein, reference numeral 105A and 103A denote a patterned polysilicon layer and a patterned conductive layer, respectively.

Meanwhile, as shown in FIG. 1D, the void or the seam 106 may increase a resistance of the gate structure.

### SUMMARY OF THE INVENTION

It is, therefore, an object of the present invention to provide a method for fabricating a recessed gate structure in a semiconductor device capable of preventing generation of a void or a seam caused by a poor step coverage property of a conductive layer.

In accordance with one aspect of the present invention, a method for fabricating a recessed gate electrode includes the steps of: selectively etching a substrate to form a plurality of openings; forming a gate oxide layer on the openings and the substrate; forming a first conductive silicon layer on the gate oxide layer to form a plurality of valleys at a height equal to or greater than a thickness remaining after an intended pattern is formed; planarizing the first conductive silicon layer until the thickness remaining after the intended pattern formation is obtained, so that the valleys are removed; forming a second conductive layer on a planarized first conductive silicon layer; and selectively etching the second conductive layer, the first conductive silicon layer and the gate oxide layer to form a plurality of the recessed gate structures.

### BRIEF DESCRIPTION OF THE DRAWINGS

The above and other objects and features of the present invention will become better understood with respect to the following description of the preferred embodiments given in conjunction with the accompanying drawings, in which:

FIGS. 1A to 1D are cross-sectional views illustrating a conventional process for forming a recessed gate structure; and

FIGS. 2A to 2E are cross-sectional views illustrating a process for forming a recessed gate structure in accordance with the present invention.

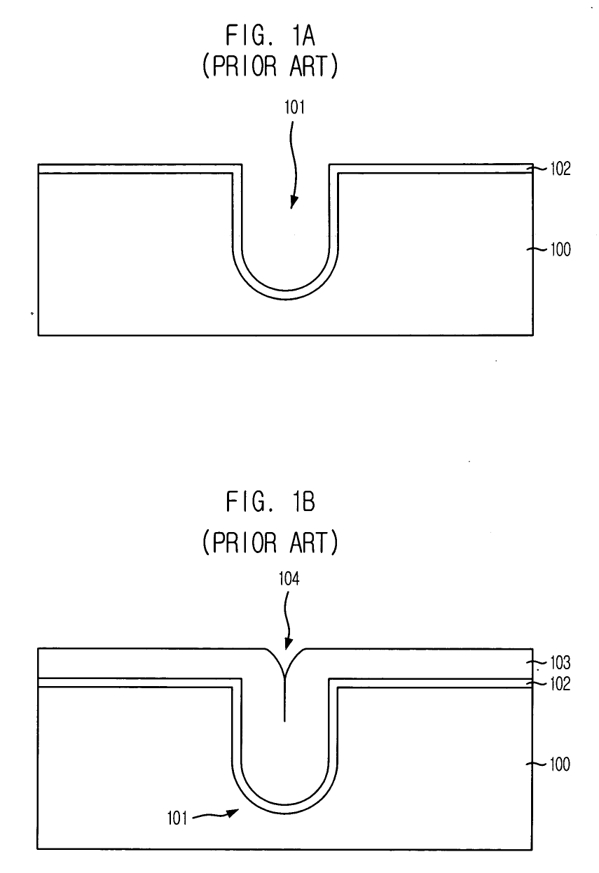

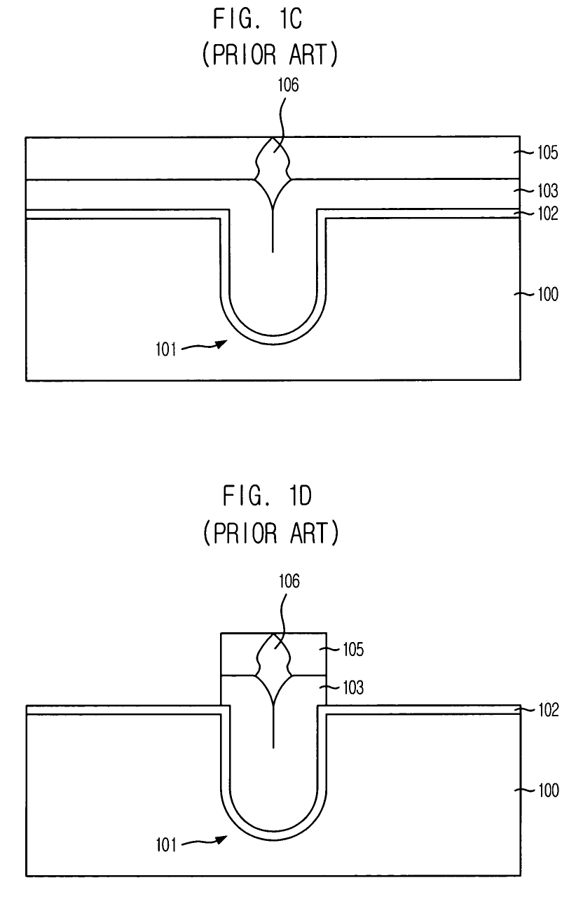

### DETAILED DESCRIPTION OF THE INVENTION

Hereinafter, detailed descriptions on a preferred embodiment of the present invention will be provided with reference to the accompanying drawings.

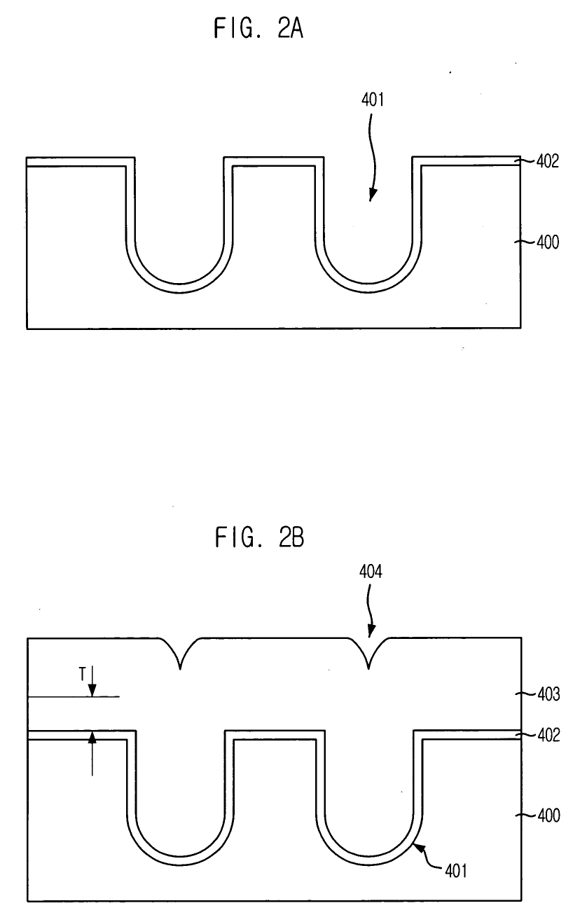

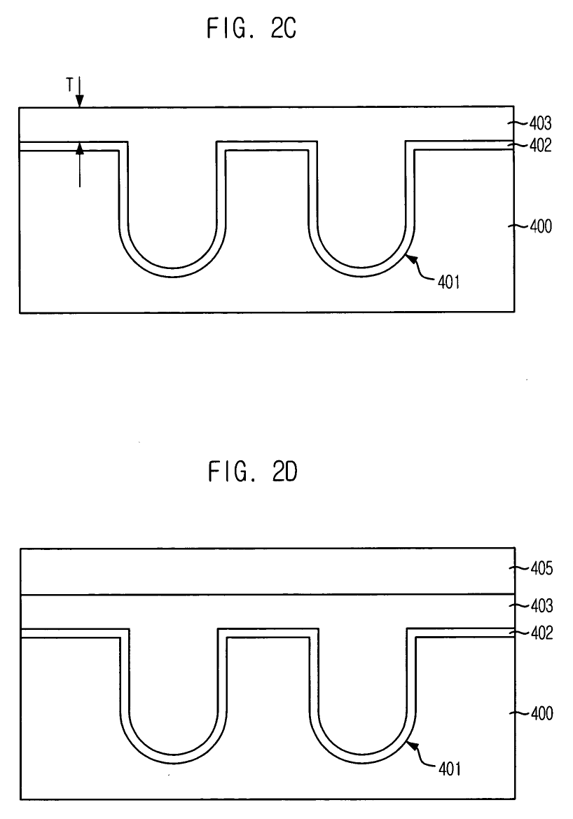

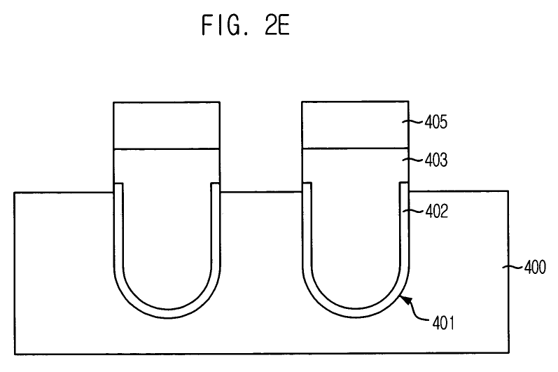

FIGS. 2A to 2E are cross-sectional views illustrating a process for forming a recessed gate structure in accordance with preferred embodiments of the present invention.

Referring to FIG. 2A, predetermined portions of a substrate 400 provided with various device elements such as a field oxide layer and wells are selectively etched. These predetermined portions of the substrate 400 are regions where transistors will be formed. That is, the substrate 400 is recessed to form a plurality of openings 401. Then, a gate oxide layer 402 is formed along a profile where the plurality of openings 401 are formed.

At this time, it is preferable to make a depth of each opening 401 ranges from approximately 1,000 Å to approximately 2,000 Å.

Subsequently, referring to FIG. 2B, a first conductive silicon layer 403 is formed on the gate oxide layer 402.

The first conductive silicon layer 403 can be formed by using one of a polysilicon layer and an amorphous silicon layer. Also, the first conductive silicon layer 403 can be formed by employing an impurity doped silicon layer or by doping impurities after the first conductive silicon layer 403 is formed.

During forming the first conductive silicon layer 403, a low pressure chemical vapor deposition (LPCVD) method having excellent step coverage property is employed.

At this time, the first conductive silicon layer 403 is deposited in a final thickness equal to or greater than a thickness T remaining after an intended pattern formation, i.e., in a thickness enough to form a valley on an upper portion of the conductive layer disposed above the remaining final thickness T. Accordingly, a plurality of valleys 404 are formed in a middle portion of each of the plurality of openings 401 allocated in an upper portion of the final thickness T remained after the intended pattern formation.

It is preferable that a deposited thickness of the first conductive silicon layer 403 is approximately 1.5 times to approximately 3 times more than depths of the plurality of the openings 401.

Subsequently, referring to FIG. 2C, during forming an intended pattern, a planarization process such as a chemical mechanical polishing (CMP) method or an etch back process is performed until the first conductive silicon layer 403 remain with the aforementioned final thickness T, and thus, the valleys 404 generated in the upper portion of the conductive silicon layer 403 are removed.

Subsequently, referring to FIG. 2D, a second conductive layer 405 having a low resistance is formed on the first conductive silicon layer 403. The second conductive layer 405 can be made of a material selected from a group consisting of tungsten (W), tungsten silicide (WSiₓ), tungsten nitride (WN) and titanium nitride (TiN).

As a result of the removal of the valleys 404, even though the step coverage property of the second conductive layer 405 is bad, a void or a seam is not produced by the planarization process applied to the first conductive silicon layer 403.

Referring to FIG. 2E, the second conductive layer 405, the first conductive silicon layer 403 and the gate oxide layer 402 are selectively etched by using a mask pattern, thereby forming a plurality of recessed gate structures. Herein, reference numerals 402A, 403A and 405A denote a patterned gate oxide layer, a patterned first conductive silicon layer and a patterned second conductive layer, respectively.

In accordance with the present invention, during forming the multi-layered and recessed gate structures the first conductive layer is formed with a thickness equal to or greater than a final thickness remaining after an intended pattern formation, i.e., with thickness enough to form the valleys. Afterwards, the first conductive silicon layer is planarized until reaching to the predetermined final thickness of the first conductive layer remaining after the intended pattern formation, thereby removing the valleys formed on the second first conductive silicon layer. Therefore, while the second conductive layer is formed, an incidence of void or seam generation caused by the valleys can be prevented, and as a result, it is further possible to prevent a resistance of the gate electrode from increasing.

The gate structure formed in accordance with the present invention can achieve a low resistance, thereby ultimately improving yields of a semiconductor device.

The present application contains subject matter related to the Korean patent application No. KR 2003-0091113, filed in the Korean Patent Office on Dec. 15, 2003, the entire contents of which being incorporated herein by reference.

While the present invention has been described with respect to certain preferred embodiments, it will be apparent to those skilled in the art that various changes and modifications may be made without departing from the spirit and scope of the invention as defined in the following claims.

What is claimed is:

1. A method for fabricating a recessed gate structure, comprising the steps of:
selectively etching a substrate to form a plurality of openings;
forming a gate oxide layer on the openings and the substrate;
forming a first conductive silicon layer on the gate oxide layer to form a plurality of valleys at a height equal to or greater than a thickness remaining after an intended pattern is formed;
planarizing the first conductive silicon layer until the thickness remaining after the intended pattern formation is obtained, so that the valleys are removed;
forming a second conductive layer on a planarized first conductive silicon layer; and
selectively etching the second conductive layer, the first conductive silicon layer and the gate oxide layer to form a plurality of the recessed gate structures.

2. The method of claim 1, wherein the first conductive silicon layer is formed with a thickness being approximately 1.5 times to approximately 3 times thicker than depths of the plurality of openings.

3. The method of claim 2, wherein the depths of the plurality of openings range from approximately 1,000 Å to approximately 2,000 Å.

4. The method of claim 1, wherein at the step of forming the first conductive silicon layer, the first conductive silicon layer attains conductivity by forming an impurity doped silicon layer.

5. The method of claim 1, wherein at the step of forming the first conductive silicon layer, the first conductive silicon layer attains conductivity by forming a silicon layer and subsequently doping impurities to the silicon layer.

6. The method of claim 1, wherein the first conductive silicon layer is one of a polysilicon layer and an amorphous silicon layer.

7. The method of claim 1, wherein the second conductive layer is made of a material selected from a group consisting of tungsten, tungsten silicide, tungsten nitride and titanium nitride.

8. The method of claim 1, wherein the step of planarizing the first conductive silicon layer proceeds by employing one of a chemical mechanical polishing method and an etch back process.

9. The method of claim 1, wherein the step of forming the first conductive silicon layer proceeds by employing a low pressure chemical vapor deposition method.

10. The method of claim 2, wherein the step of forming the first conductive silicon layer proceeds by employing a low pressure chemical vapor deposition method.

11. The method of claim 4, wherein the step of forming the conductive silicon layer uses a low pressure chemical vapor deposition method.

12. The method of claim 5, wherein the step of forming the conductive silicon layer uses a low pressure chemical vapor deposition method.

13. The method of claim 6, wherein the step of forming the conductive silicon layer uses a low pressure chemical vapor deposition method.
